(19) United States
(12) Patent Application Publication
(10) Pub. No.: US 2011/0062596 A1
(43) Pub. Date: Mar. 17, 2011

(54) SEMICONDUCTOR CHIP STACKED STRUCTURE AND METHOD OF MANUFACTURING SAME

(75) Inventors: Kei MURAYAMA, Nagano-shi (JP); Mitsuhiro Aizawa, Nagano-shi (JP)

(73) Assignee: SHINKO ELECTRIC INDUSTRIES CO., LTD.

(21) Appl. No.: 12/880,064

(22) Filed: Sep. 11, 2010

(30) Foreign Application Priority Data
Sep. 14, 2009 (JP) 2009-211367

(51) Int. Cl. H01L 23/522; H01L 21/50

(52) U.S. Cl. 257/777; 438/108; 257/E21.499; 257/E23.142

(57) ABSTRACT

A method of making a semiconductor chip stacked structure includes dicing a semiconductor wafer into semiconductor chips, the semiconductor chips respectively having a first surface and a second surface opposite thereto, the semiconductor chips having integrated circuits and pads on the first surfaces, arranging the semiconductor chips at intervals on a film having adhesive property, connecting the pads through joining members, sealing with resin the joining members and surfaces of the semiconductor chips excluding the second surfaces to produce a chip sealing structure, dividing the chip sealing structure to produce separate chip sealing structures having ends of the joining members exposed at surfaces thereof, removing the film to expose the second surfaces, stacking the chip sealing structures one over another and connecting the exposed ends of the joining members through a bonding wire to produce a chip stacked structure, and mounting the chip stacked structure on a wiring substrate.

### BACKGROUND OF THE INVENTION

1. Field of the Invention

The disclosures herein relate to a semiconductor chip stacked structure and a method for manufacturing a semiconductor chip stacked structure.

2. Description of the Related Art

A chip size package (i.e., CSP) in which a semiconductor chip is packaged is utilized as a semiconductor device mounting technology that achieves high density. A CSP is a package that is obtained by dividing and processing a semiconductor wafer including integrated circuits. CSPs may be used individually or combined together for use in mobile information devices or small-size electronic devices. The CSP technology is expected to contribute to the improved performance and further miniaturization of such devices. In response to an increase in memory capacity, for example, a chip stacked structure may be used together with the CSP technology.

As disclosed in Patent Document 1 and Patent Document 2, various studies have been made with respect to the chip stack technology. Due to the complexity of semiconductor package structures and manufacturing methods, however, the chip stack technology has not yet sufficiently satisfied the above-noted demand in the industry for improved performance and further miniaturization.

FIG. 1 is a drawing illustrating an example of a related-art chip stack. A plurality of semiconductor chips 11 are stacked one over another in a staircase fashion such that their integrated circuit surfaces 12 are parallel to the surface of a wiring substrate 13. Pads 14 arranged on edges of the semiconductor chips 11 and connection terminals 15 on the wiring substrate 13 are connected through bonding wires 16. The bonding wires connect the pads on the staircase one after another to be finally coupled to the connection pads situated on the substrate. Due to such staircase-form connections, the lengths of the bonding wires are long, which may result in degradation of electrical characteristics. Further, the chip stack staircase structure increases the total area size of the chip stack, which may undermine an effort to provide a high-density semiconductor package. Moreover, the complicated manufacturing process for stacking chips may lower productivity.

FIGS. 2A and 2B are drawings illustrating another example of a related-art chip stack. In the illustrated semiconductor package, chips 21 cut out of a semiconductor wafer are stacked together, and are electrically connected through electrically conductive epoxy 23 or the like applied by a nozzle 22. In order to provide reliable connection between the electrically conductive epoxy 23 and pads 24 on the chips 21, sloped surfaces 25 are formed on the sides of the chips. However, it is not easy to ensure narrow pitches and insulation. The illustrated technology is thus not satisfactory for the purpose of improving package density and simplifying manufacturing steps.

In order to solve one or more problems associated with a chip-stacked package, it may be desirable to improve product quality and to simplify manufacturing steps for a semiconductor package.

### [Patent Document 1] Japanese Patent Application Publication No. 2000-340694

[Patent Document 2] Published Japanese Translation of PCT application No. 10-508154

### [Patent Document 3] Japanese Patent No. 3895768

### SUMMARY OF THE INVENTION

It is a general object of the present invention to provide a semiconductor chip stacked structure and a method of making a semiconductor chip stacked structure that substantially eliminate one or more problems caused by the limitations and disadvantages of the related art.

According to one embodiment, a method of making a semiconductor chip stacked structure includes: a dicing step of dicing a semiconductor wafer into semiconductor chips, the semiconductor chips respectively having a first surface and a second surface opposite thereto, the semiconductor chips having integrated circuits and pads on the first surfaces; a first step of arranging the semiconductor chips at intervals on a film having an adhesive property with the second surfaces facing downward, connecting the pads through joining members, sealing with resin the joining members and surfaces of the semiconductor chips excluding the second surfaces to produce a chip sealing structure, and dividing the chip sealing structure to produce separate chip sealing structures having ends of the joining members exposed at surfaces thereof; a second step of removing the film to expose the second surfaces of the semiconductor chips; a third step of stacking the chip sealing structures one over another and connecting the exposed ends of the joining members through a bonding wire to produce a chip stacked structure; and a fourth step of mounting the chip stacked structure on a wiring substrate to produce a semiconductor chip stacked structure.

According to one embodiment, a semiconductor chip stacked structure includes: a plurality of chip sealing structures, each of which includes a semiconductor chip, a joining member, and resin sealing the semiconductor chip and the joining member, the semiconductor chip having a first surface and a second surface opposite thereto and having an integrated circuit and a pad on the first surface, the joining member having a first end thereof connected to the pad and a second end thereof exposed from the resin, and the second surface of the semiconductor chip being exposed from the resin; a wiring substrate having a connection terminal; and a bonding wire, wherein the plurality of chip sealing structures are stacked on the wiring substrate, and the bonding wire connects the connection terminal of the wiring substrate and the second end of the joining member of each chip sealing structure.

According to at least one embodiment, the product quality of a semiconductor package is improved, and the manufacturing steps are simplified.

### BRIEF DESCRIPTION OF THE DRAWINGS

Other objects and further features of the present invention will be apparent from the following detailed description when read in conjunction with the accompanying drawings in which:

FIG. 1 is a drawing illustrating an example of a related-art chip stack;

FIGS. 2A and 2B are drawings illustrating an example of another related-art chip stack;

FIG. 3 is a flowchart illustrating a method of manufacturing a semiconductor chip stacked structure in which a semiconductor chip sealed structure with a chip back surface being exposed is used according to a first embodiment;

FIGS. 4A through 4F are drawings illustrating semiconductor chips in each step of the method of manufacturing a semiconductor chip stacked structure according to the first embodiment;

FIGS. 5A through 5D are drawings illustrating examples of package configurations, which are illustrative of the electrical connection providing step in the manufacturing method according to the first embodiment;

FIG. 6 is a flowchart illustrating a method of manufacturing a semiconductor chip stacked structure according to a variation of the first embodiment;

FIGS. 7A and 7B are drawings illustrating dicing and setting intervals of semiconductor chips according to the variation of the first embodiment;

FIG. 8 is a flowchart illustrating a method of manufacturing a semiconductor chip stacked structure in which a chip sealing structure at the bottom layer is flip-chip mounted according to a second embodiment;

FIGS. 9A through 9C are drawings illustrating bumps formed for flip-chip connection in a chip sealing structure forming step in the second embodiment;

FIGS. 10A and 10B are drawings illustrating an example of a chip stacked structure flip-chip-mounted on a wiring substrate according to the second embodiment;

FIGS. 11A through 11C are drawings illustrating beveled corners of the chip sealing structures according to a variation of the third embodiment;

FIG. 12 is a flowchart illustrating a method of manufacturing semiconductor chip stacked structures in which semiconductor chips arranged in a matrix form are stacked one over another according to a fifth embodiment; and

FIGS. 13A through 13H are drawings for illustrating some of the steps of the method of manufacturing semiconductor chip stacked structures in which semiconductor chips arranged in a matrix form are stacked one over another.

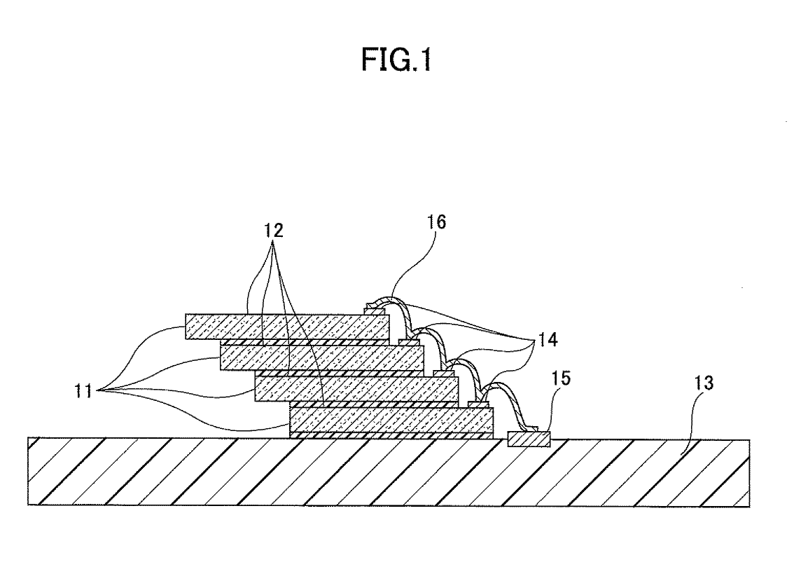

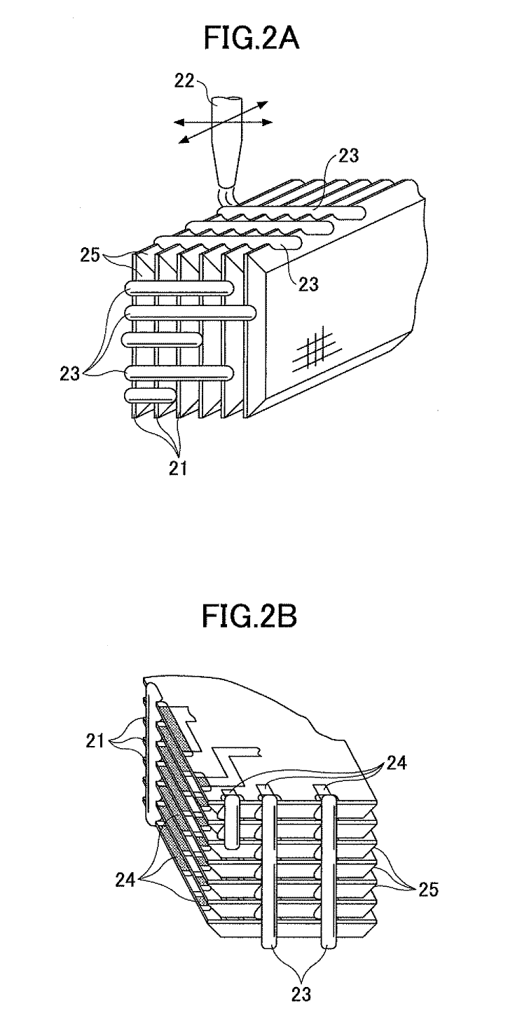

### DESCRIPTION OF THE PREFERRED EMBODIMENTS

In the following, embodiments will be described by referring to the accompanying drawings. In the description of each figure, the same elements used in one or more other figures are referred to by the same reference characters or numbers, and a duplicate description thereof may be omitted.

### First Embodiment

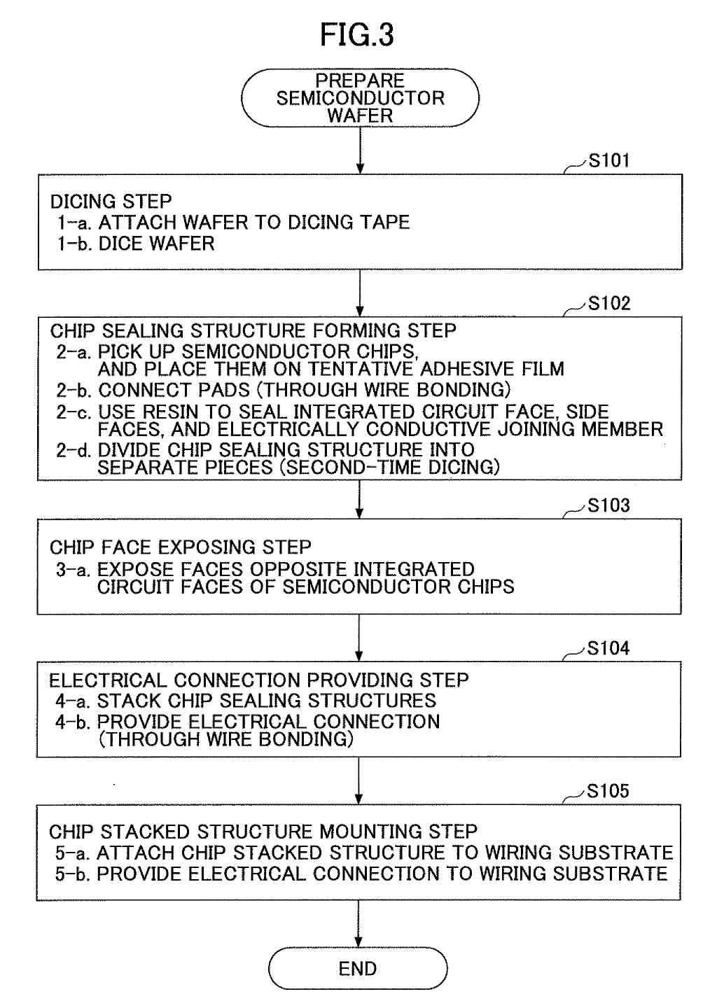

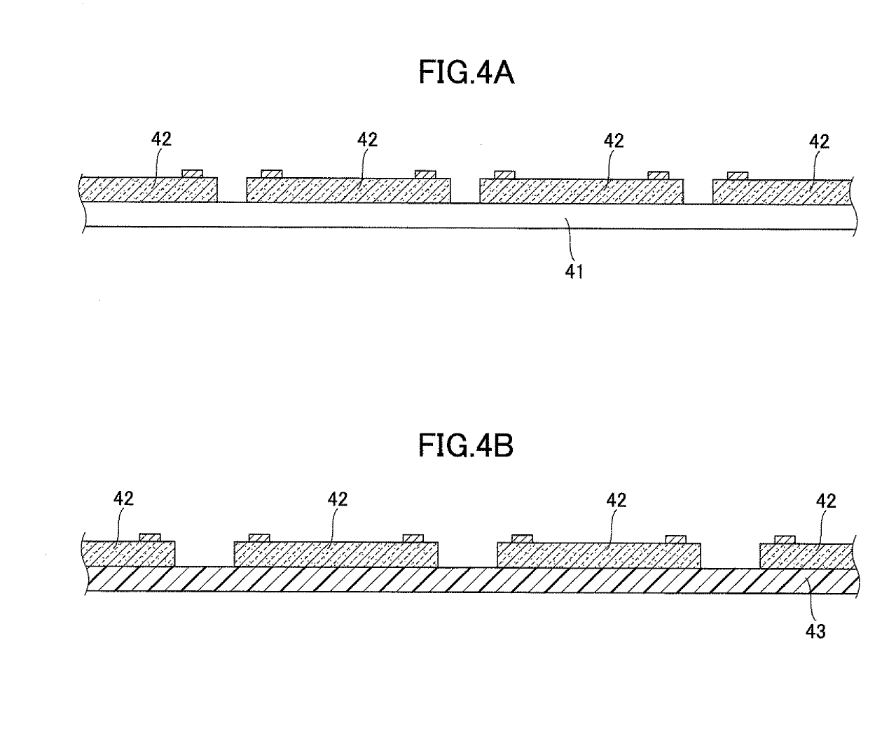

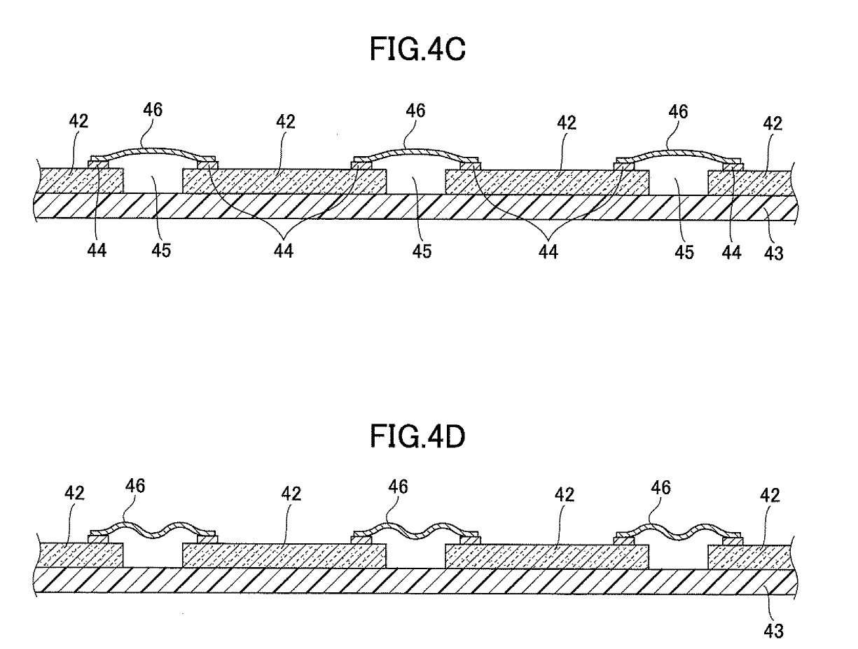

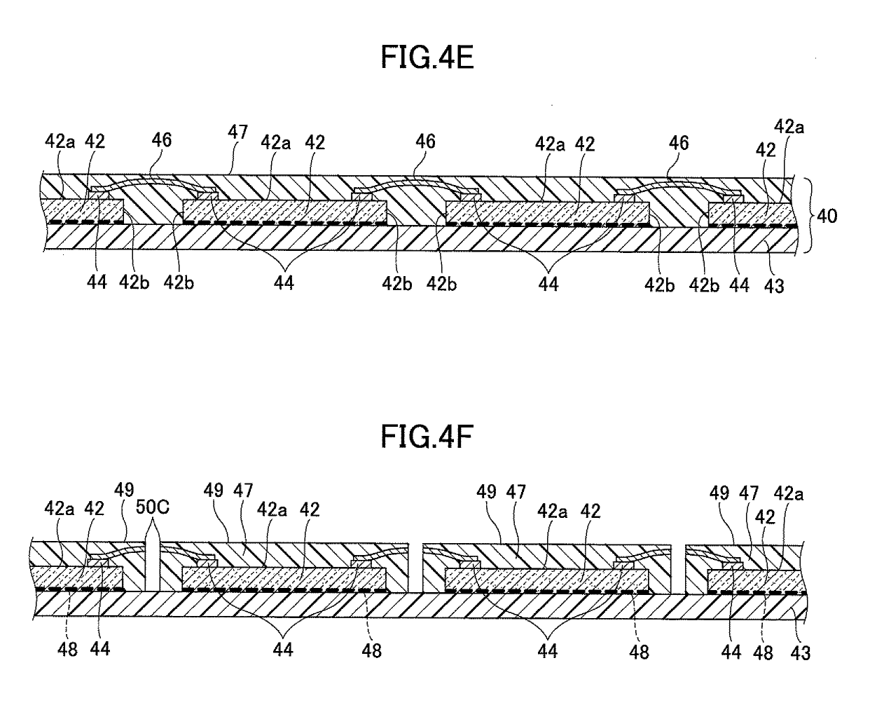

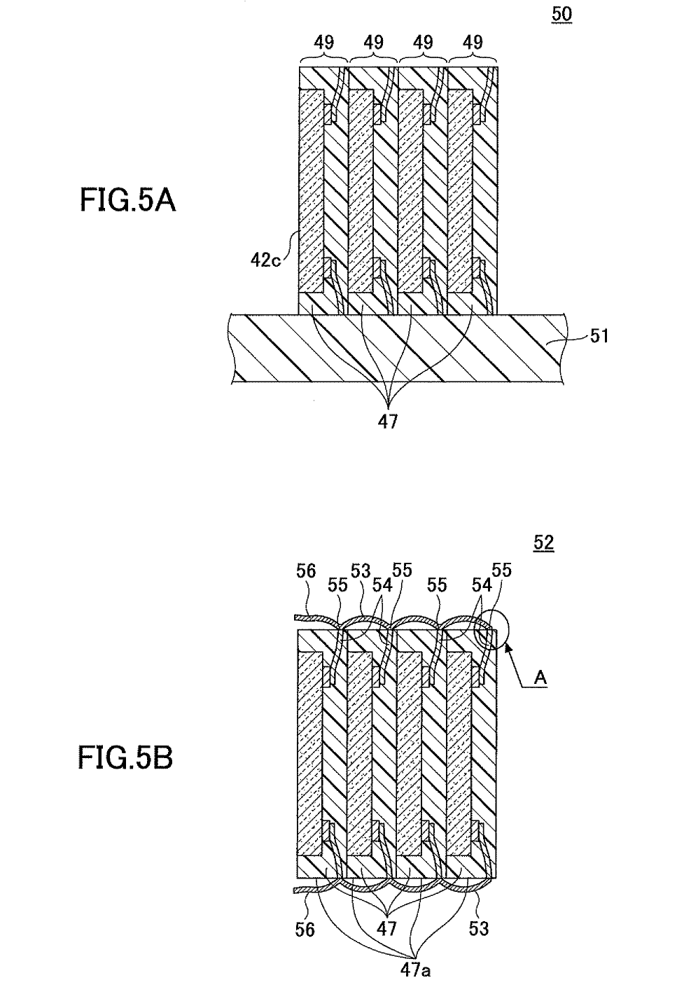

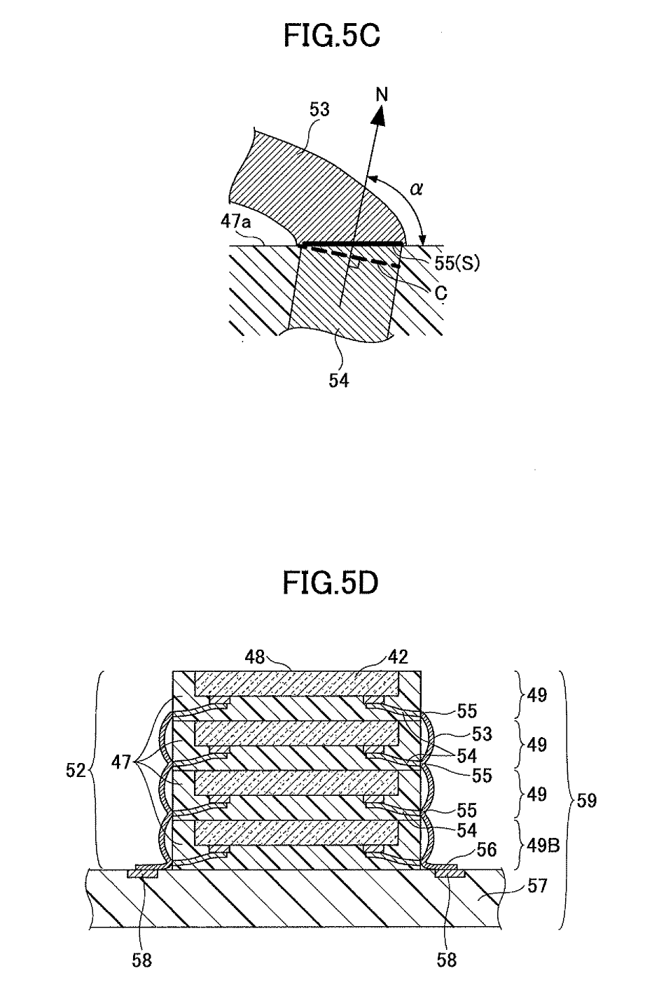

FIG. 3 is a flowchart illustrating a method of manufacturing a semiconductor chip stacked structure in which a semiconductor chip sealed structure with a chip back surface being exposed is used according to a first embodiment. The manufacturing method includes a dicing step S101, a chip sealing structure forming step S102, a chip face exposing step S103, an electrical connection providing step S104, and a chip stacked structure mounting step S105. In the following, the manufacturing method of FIG. 3 will be described step by step by referring to FIGS. 4A through 4F and FIGS. 5A through 5D, which illustrate an example of the state of a semiconductor chip at each step.

[Dicing Step S101]

A dicing tape is attached to a semiconductor wafer having a diameter of 6 inches, 8 inches, or 12 inches (sub-step 1-a in S101). Upon being mounted in a dicer apparatus, the wafer with the tape is diced into individual semiconductor chips (sub-step 1-b in S101).

FIG. 4A illustrates diced semiconductor chips 42 situated on a dicing tape 41.

[Chip Sealing Structure Forming Step S102]

The semiconductor chips are coupled through electrically conductive joining members, and are then sealed with resin, followed by being separated into individual pieces of chip sealing structures.

[Sub-Step 2-a: Picking Up Semiconductor Chip]

The diced semiconductor chips are picked up for placement at respective positions on a tentative adhesive film. In order to ensure insulation between chip sealing structures for use in a chip stacked structure, an insulating material having sufficient thickness is provided on the side faces of semiconductor chips. A proper distance between the semiconductor chips is determined based on the expected width of sealing resin situated on the side faces of the semiconductor chips and the width of dicer apparatus blades (e.g., 25 micrometers to 30 micrometers) for dividing the chip sealed structure. The use of an optical-system-based positioning mechanism makes it possible to achieve sufficient placement position accuracy at the time of placing the semiconductor chips.

FIG. 4B illustrates the semiconductor chips 42 placed on a tentative adhesive film 43. River Alpha of Nitto Denko Corporation may be used as the tentative adhesive film 43.

[Sub-Step 2-b: Connecting Pads (Wire Bonding)]

FIG. 4C illustrates connections between pads 44. The pads 44 on the semiconductor chips 42 spaced apart from each other are connected through electrically conductive joining members (e.g., bonding wires) 46 by use of a bonding apparatus (not shown). The diameter of bonding wires is typically 20 micrometer to 30 micrometers. For the purpose of providing easy connection, bonding wires having a thicker diameter may be utilized. The elevation of the peaks of connected bonding wires may be around 40 micrometers from the integrated circuit face of the semiconductor chips. The material of electrically conductive joining members may be gold, aluminum, copper, tungsten, or an alloy of some or all of these. Bonding ribbons may be used in place of bonding wires.

The pads are connected with each other across gaps 45 between the semiconductor chips. Such connections across the gaps are suitable for the purpose of exposing the bonding wires 46 at the resin surfaces after dividing the chip sealing structure into individual pieces in sub-step 2-d illustrated in FIG. 3.

The shape of the bonding wires 46 connecting between the pads is not limited to a round arch as illustrated in FIG. 4C, but may be formed in a letter-M shape as viewed from the side as illustrated in FIG. 4D. This bonding wire shape is used to impart a wide surface area to the exposed bonding wires at the resin surfaces, thereby allowing reliable electrical coupling at the time of providing electrical connections (sub-step 4-b in FIG. 3). The shape as viewed from the side is not limited to a letter-M shape, and may be configured such that the shape of a bonding wire connecting between connection points as defined in a plane containing such a bonding wire is a curve that has at least one dent.

[Sub-Step 2-c: Sealing Integrated Circuit Face, Side Faces, and Electrically Conductive Joining Members]

FIG. 4E is a drawing illustrating a chip sealing structure 40. Resin 47 seals the electrically conductive joining members (i.e., bonding wires) 46, side faces 42b, and principal surfaces 42a in which the integrated circuits of the semiconductor chips 42 are formed. Surfaces 48 opposite the principal surfaces 42a of the semiconductor chips 42 are adhered to the tentative adhesive film 43 and are thus not sealed by resin. These surfaces 48 will be exposed as a sealing structure surface in subsequent step S103 in which the tentative adhesive film 43 is removed.

An epoxy resin may be used as the sealing resin.

<Two Cured States of Sealing Resin>

The disclosed manufacturing method utilizes two cured states of the sealing resin 47 for different purposes in respective process steps.

A first cured state which is a semi-cured state (i.e., B stage) is maintained for several process steps before the process step in which the sealing resin 47 is fully cured into a second cured state.

In the first cured state, the resin is kept in a semi-cured state to maintain its exterior shape while retaining low elasticity, and, also, its tackiness is utilized. The semi-cured state of resin is maintained in each step from sub-step 2-d in S102 (i.e., dividing the chip sealing structure) to sub-step 5-a in S105 (i.e., attaching a chip stacked structure to a substrate).

Low elasticity kept in the first cured state (i.e., semi-cured state) is meant to maintain the shape of electrically conductive joining members (i.e., bonding wires) that can be easily bent. For the purpose of securing reliable electrical connection by use of a bonding wire having a large connection surface area, the axis of the bonding wire is kept at a predetermined angle relative to the edge surface of sealing resin. Specifically, the bonding wire is shaped into a round arch or a letter-M shape (see FIG. 4D). Low elasticity resin is used for the sealing purpose so that the shape of bonding wires is not deformed by the flow of resin.

The ability to maintain the exterior shape of sealing resin is important in order to avoid deformation under a cutting force applied in the cutting step performed by a dicer apparatus in the sub-step 2-d of dividing the chip sealing structure.

The tackiness is meant to provide an adhesive property utilized for stacking plural chip sealing structures one over another and also for joining the chip stacked structure to a wiring substrate.

WL-NCF of Toray Industries, INC., for example, may be used as the sealing resin as its low elasticity property is suitable for the process steps during which the first cured state (i.e., semi-cured state) is maintained.

Young's modulus of resin may be kept in the range of 1 MPa to 20 GPa, for example, for the purpose of maintaining the exterior shape of resin under a cutting force applied by a dicer apparatus.

The second cured state imparts a rigid body property to the sealing resin. This rigid body property ensures that the sealing resin serves as a housing to provide protection and support functions at the time of mounting the chip stacked structure to a wiring substrate. Well-known pressurizing and curing processes achieve the rigid body property.

[Sub-Step 2-d: Dividing Chip Sealing Structure into Separate Pieces]

The chip sealing structure 40 (FIG. 4E) is divided into pieces by a dicer apparatus (not shown) to provide chip sealing structures for use in manufacturing a semiconductor chip stacked structure.

FIG. 4F is a drawing illustrating an example of chip sealing structures 49 that are obtained by dividing the chip sealing structure 40. The intervals between the separated chip sealing structures 49 may be 20 micrometers to 30 micrometers, for example. The tentative adhesive film 43 is not cut at the time of dividing the chip sealing structure so as to be able to support the divided chip sealing structures as a dicing tape works at the time of dicing a wafer.

When the dice apparatus uses a flat blade, the chip sealing structures have a right-angle edge at corners 50C as illustrated in FIG. 4F.

[Chip Surface Exposing Step S103]

The tentative adhesive film 43 is removed or peeled off from the back surfaces of the semiconductor chips, i.e., the surfaces opposite the integrated circuit surfaces of the semiconductor chips. As a result, the back surfaces of the semiconductor chips are exposed. The chip sealing structures may be picked up to disconnect them from the tentative adhesive film 43, thereby exposing the chip back surfaces.

[Electrical Connection Providing Step S104]

The chip sealing structures are stacked one over another, and are then electrically connected with each other.

[Sub-Step 4-a: Stacking Chip Sealing Structures]

The chip sealing structures 49 illustrated FIG. 4F are picked up, and are arranged to face the same direction, followed by being stacked one over another. The chip sealing structures 49 are removed from the tentative adhesive film 43 at the time of pick up. The back surface 48 opposite the principal surface 42a of each semiconductor chip is exposed at the surface of the sealing resin. Upon making a stack, this exposed surface is covered by the semi-cured resin of another chip sealing structure, so that all the surfaces of semiconductor chips will be sealed, with one exception. As illustrated in FIG. 5A, for example, a back surface 42c of the semiconductor chip arranged at one end is still exposed. This exposed surface may be utilized as a heat sink surface, which may be connected to a heat sink fin. Alternatively, this exposed surface may be sealed by additional resin. Either configuration may be used in accordance with use conditions.

FIGS. 5A through 5D are drawings illustrating examples of package configurations, which are illustrative of the electrical connection providing step in the manufacturing method according to the first embodiment. On the chip back surface of a given chip sealing structure, no resin of this chip sealing structure is disposed, providing no resin thickness, which is different from a conventional chip sealing structure. Since the chip sealing structures with the chip back surfaces being exposed are stacked one over another, the thinness of the individual chip sealing structure contributes to the thinness of the total package that contains a chip stacked structure.

FIG. 5A is a drawing illustrating an example of a chip stacked structure 50 that is obtained by stacking chip sealing structures. The chip sealing structures 49 are stacked one over another via the sealing resin 47 so as to form the chip stacked structure 50 placed on a support platform 51. In the process of making a stack, the chip sealed structures are pressurized while the sealing resin 47 is kept in the semi-cured state (i.e., B stage). The back surfaces of the semiconductor chips that are exposed at the surfaces of sealing resin may be processed into rough surfaces in order to provide more secure connection with the resin. The process of making rough surfaces may be performed on the entire back surface of the wafer before the dicing tape is attached in the dicing step S101.

[Sub-Step 4-b: Providing Electrical Connections (Wire Bonding)]

The ends of electrical conductive joining members that are exposed at the surfaces of the chip sealing structures 49 are connected through electrically conductive bonding wires.

FIG. 5B is a drawing illustrating an example of a chip stacked structure 52 that is obtained by providing electrical connections through bonding wires.

It may be preferable to secure a large area size at the connection point of the electrically conductive joining members when the electrically conductive joining members are connected to the bonding wires.

FIG. 5C is a drawing illustrating an enlarged view of a portion A illustrated in FIG. 5B. An electrically conductive joining member 54 is electrically connected to a bonding wire 53 at an end face 55 exposed at a resin side face 47a. An angle α formed between the resin side face 47a and an axis N of the electrically conductive joining member 54 at the end face 55 may be made smaller than the right angle by bending the electrically conductive joining member 54. This increases the surface area of the end face 55, thereby providing a secure electrical connection. A cross-section C of the electrically conductive joining member 54 may be a circle. In such a case, the angle α formed between the axis N and the end face 55 may be made smaller than 90 degrees to provide an ellipse cross-section S, the area size of which is approximately 1/sin α times as large. In order to change the angle α, the electrically conductive joining member 54 is bent to form a curve that has a letter-M shape or has at least one dent. Such a shape may be formed by controlling the movement of a wire bonder capillary.

The material of the bonding wire 53 may be gold, aluminum, copper, tungsten, or an alloy of some or all of these. When aluminum is used, the diameter may generally be 100 micrometers or less, and room-temperature bonding is possible. In FIG. 5B, bonding is consecutively performed at once by a wire bonder apparatus (not shown) with respect to the end faces 55 of the electrically conductive joining members 54 exposed at the side faces of the stacked chip sealing structures 49. The bonding wire 53 providing electrical connections may be situated apart from the resin side faces of the chip sealing structures, or may be in contact with these resin side faces. An end portion 56 of the bonding wire 53 serves as a terminal for connection with a wiring substrate.

[Chip Stacked Structure Mounting Step S105]

The chip stacked structure mounting step that mounts such a structure to a wiring substrate produces a completed package product that includes a semiconductor chip stacked structure.

FIG. 5D is a drawing illustrating an example of a semiconductor chip stacked structure 59 that is obtained by mounting and electrically connecting a chip stacked structure.

[Sub-Step 5-a: Attaching Chip Stacked Structure to Wiring Substrate]

The chip stacked structure 52 having electrical connections provided between the sealed chips is placed on a wiring substrate 57. A sealed chip 49B at the bottom layer faces the wiring substrate 57, and is adhered to the surface of the wiring substrate 57 via the semi-cured-state resin 47.

Well-known processes of pressurizing and curing resin are then performed to change the state of the resin 47 into the second cured state that provides the rigid body property.

[Sub-Step 5-b: Connecting Wires to Substrate]

The end portions 56 of the bonding wires are connected to connection terminals 58 of the wiring substrate 57, with which the process of manufacturing the semiconductor chip stacked structure 59 comes to an end.

### Advantage of First Embodiment

The surfaces of semiconductor chips opposite the principal surfaces thereof are not covered with sealing resin, which serves to reduce the thickness of a semiconductor package, with the reduced thickness being equal to the total thickness of otherwise-provided sealing resin layers. The performance of the end-result product may thus be improved. Further, the manufacturing process is simplified to reduce the production cost.

### Variation of First Embodiment

In the sub-step 2-a of placing semiconductor chips on a tentative adhesive film according to the first embodiment, the semiconductor chips are placed at respective positions on the tentative adhesive film in order to provide sufficient spacing intervals between the semiconductor chips. In a variation thereof, placement for providing spacing intervals is achieved by use of another means. That is, a dicing tape for supporting a semiconductor wafer at the time of dicing is stretched and expanded in the radial directions of the wafer after the dicing, thereby providing sufficient spacing intervals between the semiconductor chips.

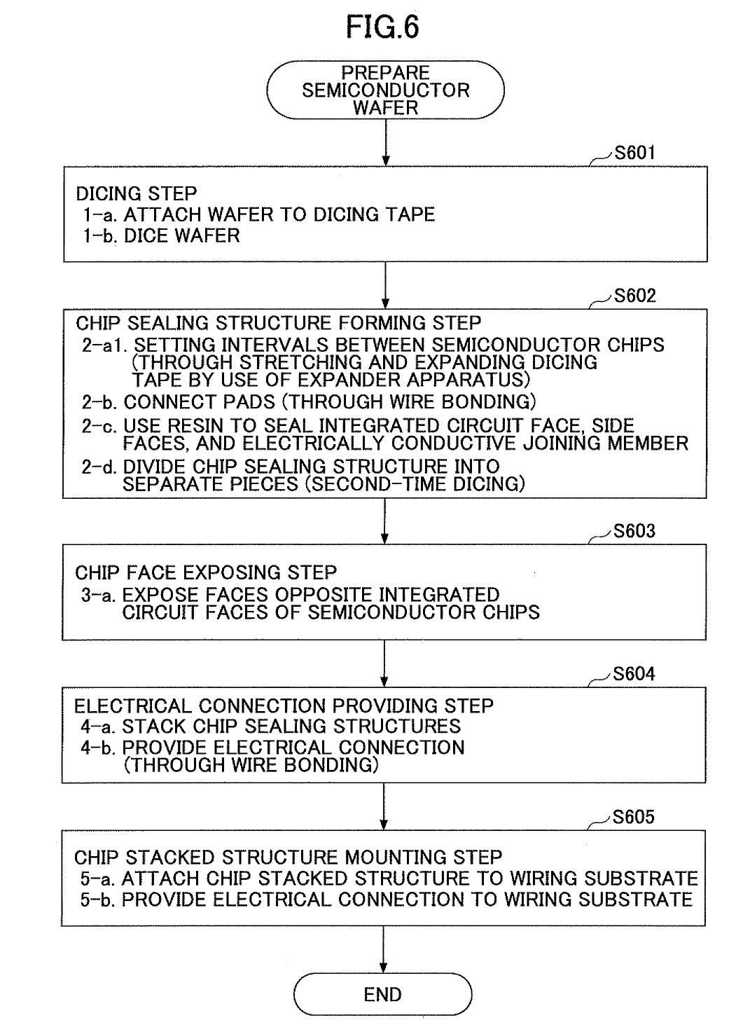

FIG. 6 is a flowchart illustrating a method of manufacturing a semiconductor chip stacked structure according to the variation of the first embodiment.

The manufacturing method includes a dicing step S601, a chip sealing structure forming step S602, a chip face exposing step S603, an electrical connection providing step S604, and a chip stacked structure mounting step S605. Steps S602 and S604, which are different from the corresponding steps of the first embodiment, will be described below, and a duplicate description of the remaining steps will be omitted.

[Chip Sealing Structure Forming Step S602]

This step differs from the step S102 of the first embodiment in the way spacing intervals are provided in sub-step 2-a1 between semiconductor chips.

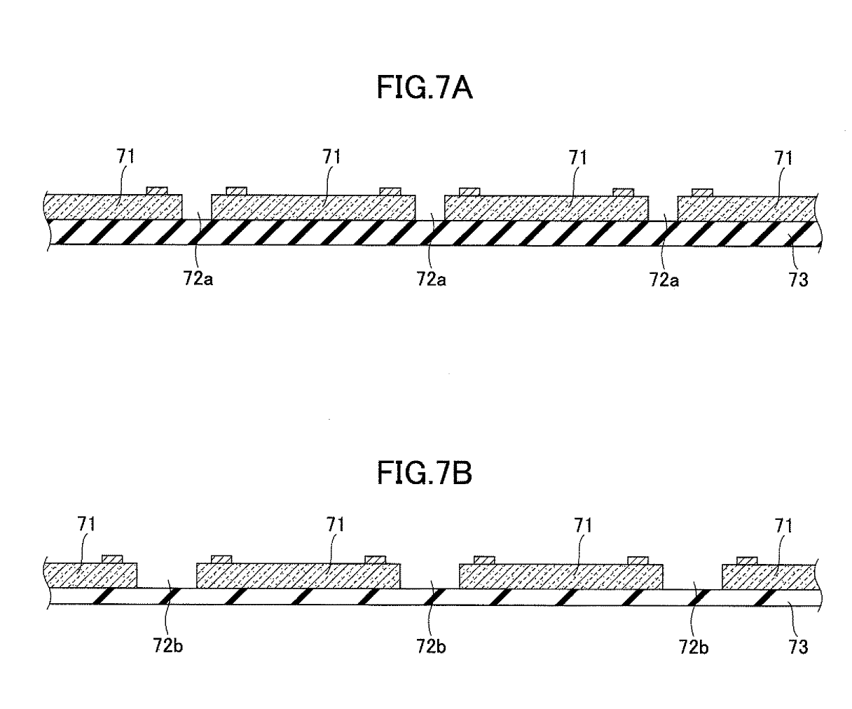

FIG. 7A is a drawing illustrating semiconductor chips after dicing is completed in step S601. FIG. 7B is a drawing illustrating semiconductor chips after spacing intervals are provided between the semiconductor chips by stretching and expanding a dicing tape in sub-step 2-a1. Intervals 72a are provided between semiconductor chips 71 that are segmented by dicing in step S601. Edges of a dicing tape 73 are held by a dicing ring (now shown) and pulled outwardly in the radial directions, thereby expanding the dicing tape 73 to widen the intervals. Intervals 72b are thus obtained between the semiconductor chips 71. This expansion may be performed by attaching the dicing tape 73 held by the dicing ring to an expander apparatus. The spacing intervals 72b between the semiconductor chips 71 may generally be 100 micrometers to 200 micrometers, and may be further widened to 100 micrometers depending on sealing conditions. The remaining aspects of the chip sealing structure forming step are the same as those of the first embodiment.

[Electrical Connection Providing Step S604]

This step is the same as the corresponding step of the first embodiment, except that the picking up of individual chip sealing structures results in these structures being removed from the dicing tape instead of the tentative adhesive film 43.

### Advantage of Variation of First Embodiment

No tentative adhesive film is used, and no step of placing semiconductor chips on a tentative adhesive film is performed after dicing. Manufacturing steps are thus simplified to reduce production cost.

### Second Embodiment

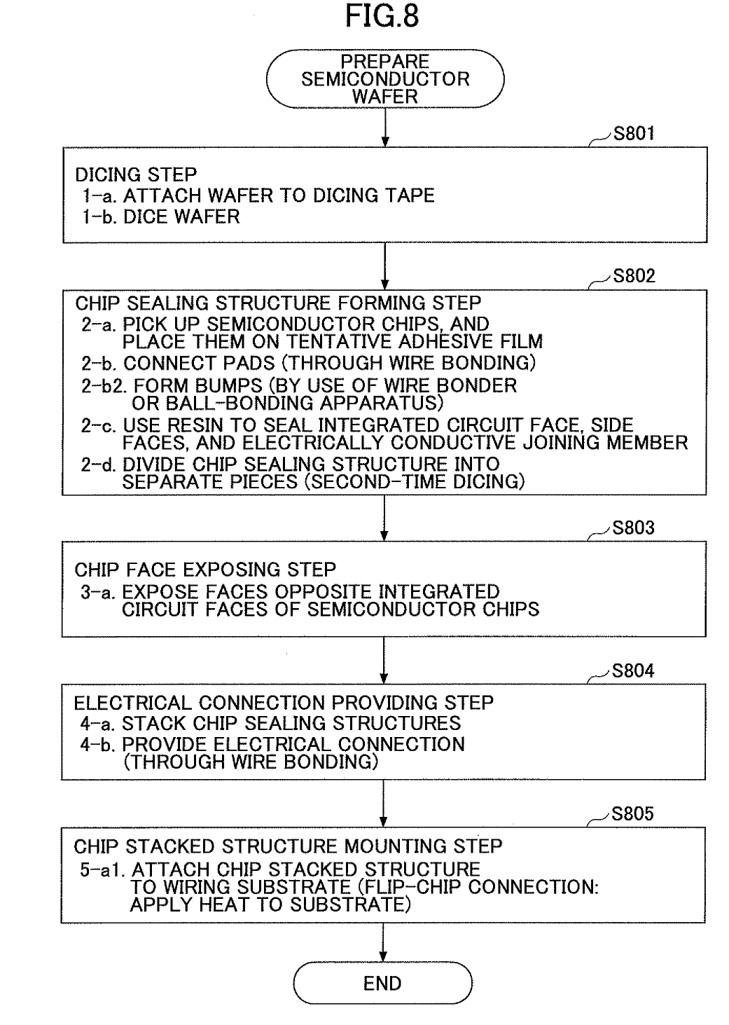

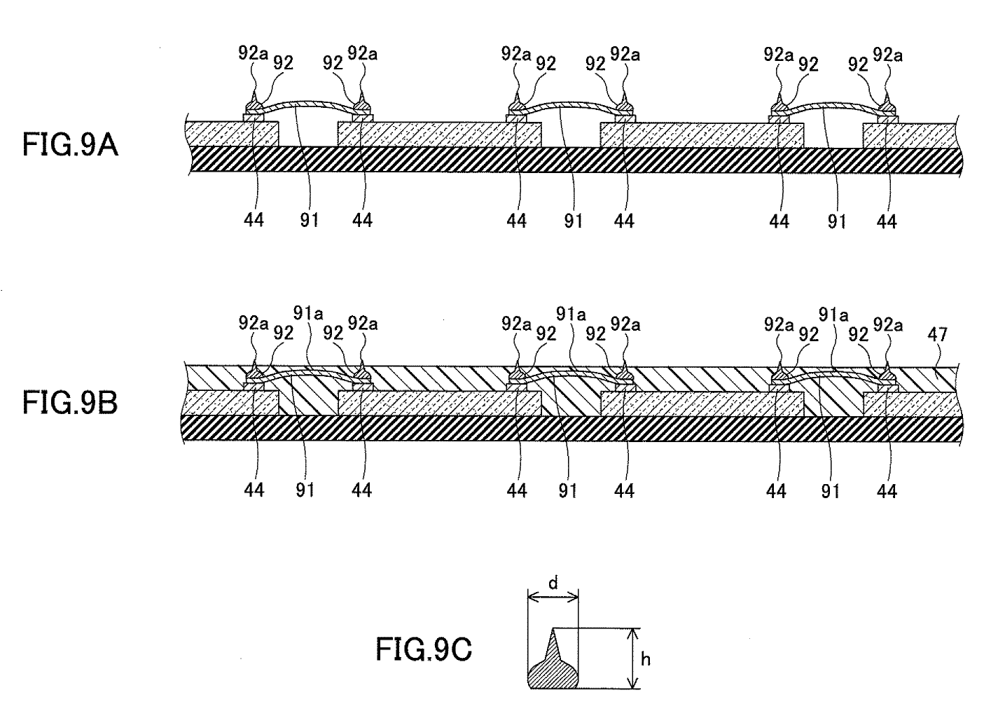

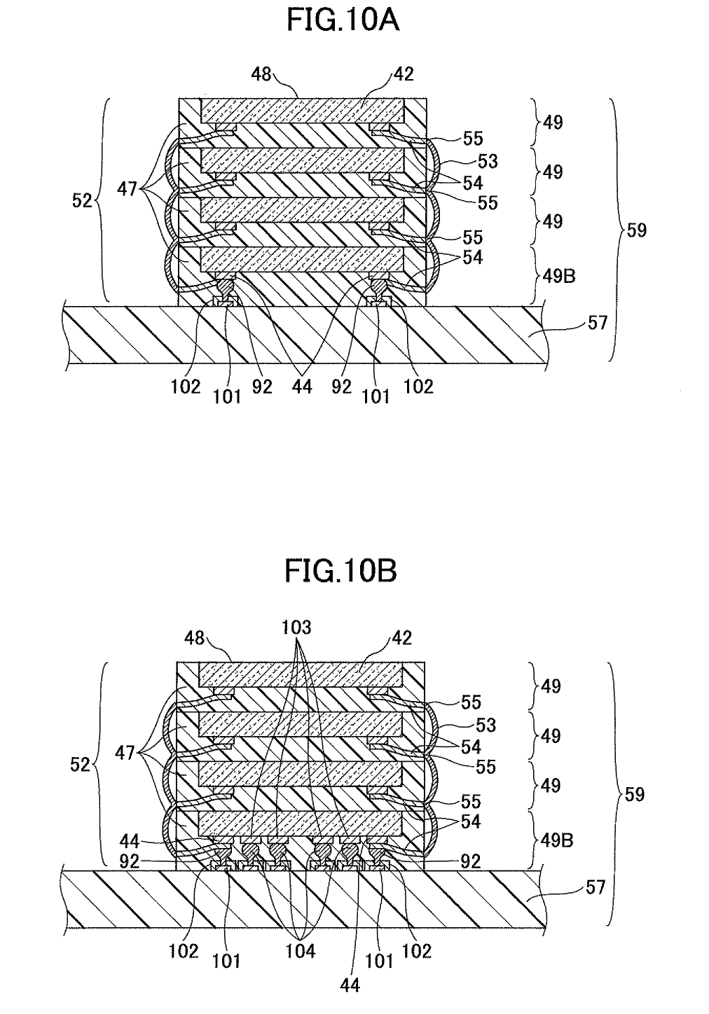

FIG. 8 is a flowchart illustrating a method of manufacturing a semiconductor chip stacked structure in which a chip sealing structure at the bottom layer is flip-chip mounted on a wiring substrate according to a second embodiment. The manufacturing steps of the second embodiment differ from the manufacturing steps of the first embodiment in the forming of bumps in sub-step 2-b2 and the mounting (i.e., flip-chip mounting) of a chip stacked structure to a substrate in sub-step 5-a1. These two steps will be described below by referring to FIGS. 9A through 9C and FIGS. 10A and 10B. A description of the remaining steps will be omitted in order to avoid duplicate explanations.

[Sub-Step 2-b2: Forming Bumps in Chip Sealing Structure Forming Step S802]

FIGS. 9A through 9C are drawings illustrating bumps formed for flip-chip connection in the chip sealing structure forming step S802. FIG. 9A illustrates the state of bumps that have just been created. FIG. 9B illustrates the state of bumps after sealing is provided by insulating resin. FIG. 9C illustrates a single bump.

As illustrated in FIG. 9A, bumps 92 are created at the positions of the pads 44 on bonding wires 91 connecting between the pads 44. The bumps 92 having a pointing head 92a may be formed by using a wire bonder as follows.

A tip of a bonding wire (not shown) that is passed through a wire bonder capillary is heated to form a ball for use as a bump. A tip of the capillary utilizes heat or ultrasonic vibration to perform pressure bonding, thereby attaching the ball tip of the bonding wire to a bonding wire 91 connecting between pads. After the ball is fixedly mounted, the wire is torn off by use of a clamp or the like, thereby forming the bump 92 having the pointing head 92a.

As illustrated in FIG. 9B, the sealing resin 47 is used as sealing after the bumps 92 are formed. The pointing heads 92a of the bumps 92 are exposed at the surface of the resin layer by penetrating the layer of the sealing resin 47 in the semi-cured state. This makes it possible to easily and smoothly perform flip-chip mounting to a wiring substrate.

The material of the bumps 92 may be gold, copper, or the like, for example. Aluminum may be used depending on connection conditions. In respect of FIG. 9C, the size of the bump 92 may be such that a diameter d is 17 to 60 micrometers, and a height h is 15 to 60 micrometers. The height h is higher than peaks 91a of the bonding wires 91 for the purpose of flip-chip connection (see FIG. 9B). The bumps may be formed, instead of by using a wire bonder, by using a ball-bump placing apparatus or the like, which may fixedly attach a ball bump on a bonding wire 91. The use of a ball bump does not create a pointing head, which would be created if a wire bonder was used. However, when the chip stacked structure is flip-chip mounted on a wire substrate, the resin is still in the semi-cure state. The ball bumps can thus penetrate the resin layer to be exposed from the surface of the resin. Accordingly, sufficient electrical connections with the wiring substrate are secured.

[Sub-Step 5-a1: Attaching Chip Stacked Structure to Wiring Substrate in Chip Stacked Structure Mounting Step S805]

FIGS. 10A and 10B are drawings illustrating an example of a chip stacked structure flip-chip-mounted on the wiring substrate 57. FIG. 10A illustrates the bumps 92 situated at the positions of electrically conductive joining members 54 on the pads 44. FIG. 10B illustrates additional bumps 104 situated on additional pads 103 to which the electrically conductive joining members 54 are not connected. These bumps are flip-chip connected to the wiring substrate 57.

Solder terminals 102 for use in flip-chip mounting are formed on the wiring substrate 57 to cover connection terminals 101. An alloy of materials such as tin, silver, and copper may be used as the solder.

The chip stacked structure 52 and the wiring substrate 57 are aligned as to their positions. The wiring substrate 57 is then heated to melt the solder terminals 102. The heating temperature for melting the solder may be 230 degrees Celsius, for example.

The bumps 92 of the chip stacked structure 52 may not be sufficiently exposed from the resin 47, depending on the surface conditions of the resin 47. Even in such a case, since the resin 47 is in the semi-cured condition, the bumps 92 penetrate the resin 47 to be exposed from the resin surface when the chip stacked structure 52 is pressed against the wiring substrate 57 at the time of mounting. The bumps 92 are thus connected to the solder terminals 102, thereby coupling the chip stacked structure 52 to the wiring substrate 57.

### Advantage of Second Embodiment

A manufacturing method is provided to mount a chip stacked structure on a wiring substrate in a flip-chip manner. With this method, a small-size chip stacked structure comparable in size to the chips can be mounted on the wiring substrate in a short time. The productivity and quality of semiconductor chip stacked structures can thus be improved. Further, the method of providing flip-chip connection as illustrated in FIG. 10B can expand the range of semiconductor chip types that can be used in the semiconductor chip stacked structure. For example, a CPU serving as a logic circuit having a large number of terminals may be stacked with memory semiconductor chips, thereby contributing to functional expansion.

### Third Embodiment

The third embodiment is directed to a semiconductor chip stacked structure that includes a wiring substrate and a stack of plural chip sealing structures each of which has the back surface of the chip being exposed.

FIG. 5D previously described illustrates the semiconductor chip stacked structure 59. The semiconductor chip stacked structure 59 is configured such that the chip stacked structure 52 made of the plural chip sealing structures 49 is stacked on the wiring substrate 57. In each chip sealing structure 49, the semiconductor chip 42 having semiconductor integrated circuits and pads 44 on one surface thereof is sealed with the resin 47 such that the back surface opposite the integrated circuit surface is exposed. An epoxy resin may be used as the sealing resin. The pads 44 provided on the integrated circuit surface are connected to the electrically conductive joining members 54, with one end 55 of each pad exposed at the side faces of the sealing resin 47. Each electrically conductive joining member 54 is connected at the end face 55 thereof to a bonding wire 53. The end portion 56 of the bonding wire 53 is connected to a connection terminal 58 of the wiring substrate 57.

In this configuration of the semiconductor chip stacked structure 59, the sealing resin 47 constituting the chip sealing structures 49 serves to provide an adhesive function when the chip sealing structures 49 are adhered to each other in the stack configuration and also when the chip stacked structure 52 made of the chip sealing structures 49 is adhered to the wiring substrate 57. The sealing resin is kept in the semi-cured state to provide reliable connection.

### Advantage of Third Embodiment

A chip stacked structure is provided by mounting on a wiring substrate a stack of semiconductor chip sealing structures, which have no resin on the back surfaces of the semiconductor devices. Since each chip sealing structure does not have a resin layer on the chip back surface, the thickness is reduced in the absence of otherwise provided resin layers. This achieves a thinner structure of a semiconductor package, thereby improving product performance.

Further, the back surface of the semiconductor chip at the top layer of the semiconductor package is exposed from the sealing structure. This provides a high heat releasing effect for the semiconductor chip.

### Variation of Third Embodiment

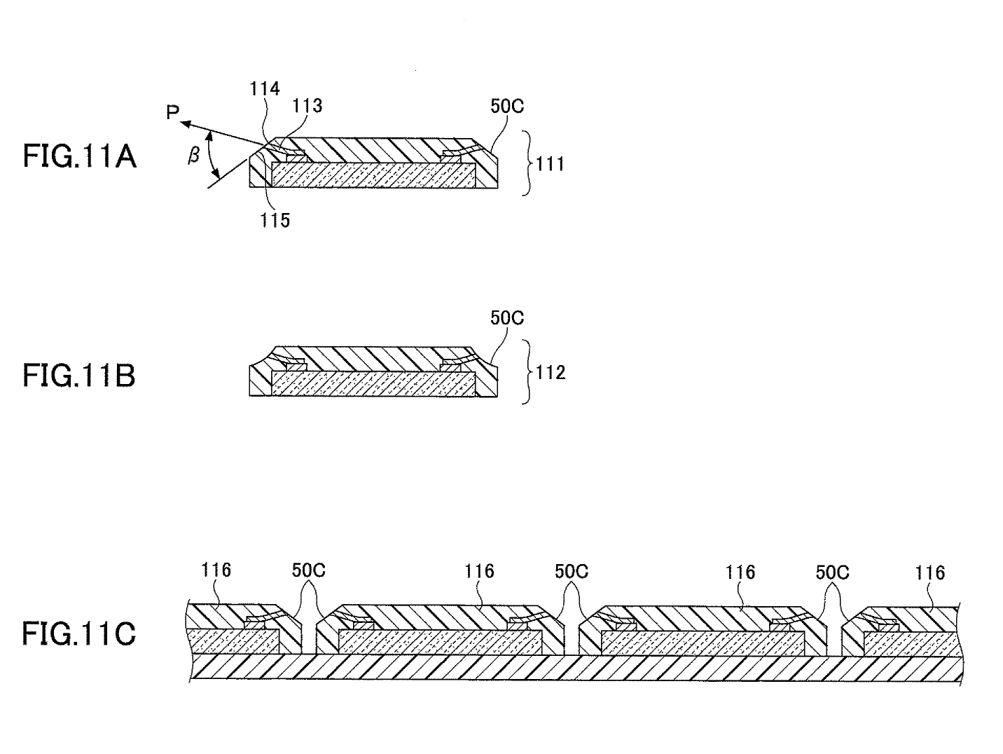

FIGS. 11A through 11C are drawings illustrating beveled corners of the chip sealing structures according to a variation of the third embodiment. Corners 50C are beveled, so that the angle at which the electrically conductive joining members are cut is set equal to a sharp angle. This serves to broaden the connection faces of the electrically conductive joining members that meet bonding wires. Beveling is performed to provide a flat surface in FIG. 11A, and is performed to provide a curved surface in FIG. 11B. In FIG. 11A, a flat beveled surface is provided at the corners of chip sealing structures 111, thereby forming an angle βsmaller than the right angle between a resin surface 115 and the axial direction P of an electrically conductive joining member 113 at an end face 114 thereof. This arrangement serves to provide a reliable electrical connection as in the case of FIG. 5C, in which the electrically conductive joining member 54 is bent such that the angle α is provided to make an ellipse shape at the end face of the electrically conductive joining member 54 for the purpose of enlarging the surface area. In FIG. 11B, the surface area of the end face of an electrically conductive joining member is enlarged, and, also, the provision of the convex connection surface facilitate a reliable connection.

Beveling may be performing with respect to the corners 50C by using a bevel-cut-purpose blade or plural blades for dual dicing at the sub-step 2-d of dividing the chip sealing structure into pieces in step S102 illustrated in FIG. 3.

FIG. 11C illustrates diced chip sealing structures 116 for which beveling has been completed with respect to the corners 50C of each chip sealing structure.

### Advantage of Variation of Third Embodiment

A reliable electrical connection is provided by enlarging the surface areas of end faces of the electrically conductive joining members. This improves production quality.

### Fourth Embodiment

The fourth embodiment is directed to a semiconductor chip stacked structure in which the chip sealing structure at the bottom layer is flip-chip mounted to a wiring substrate, and the back surface of the semiconductor chip of the top-layer chip sealing structure is exposed.

In FIG. 10A that illustrates a chip stacked structure mounted in a flip-chip manner, the chip stacked structure 52 has the bumps 92 on the electrically conductive joining members 54 at the positions of the pads 44 of the semiconductor chip 42. In FIG. 10B, the chip stacked structure 52 also has the bumps 104 on the pads 103 to which the electrically conductive joining members 54 are not connected.

### Advantage of Fourth Embodiment

According to the fourth embodiment, the types of semiconductor chips usable in the package configuration using a semiconductor chip stacked structure are expanded. For example, a CPU serving as a logic circuit having a large number of terminals may be stacked with memory semiconductor chips, thereby contributing to functional expansion. Further, a semiconductor chip stacked structure, in which the chip sealing structures each having an exposed semiconductor chip back surface are stacked one over another, is provided to achieve a high heat releasing characteristic for the semiconductor chip. With this arrangement, the product range is expanded, and the product functions are improved.

### Fifth Embodiment

In this embodiment, plural chip stacked structures are simultaneously formed by forming stacks from semiconductor chips that are arranged in a matrix form on a tentative adhesive film.

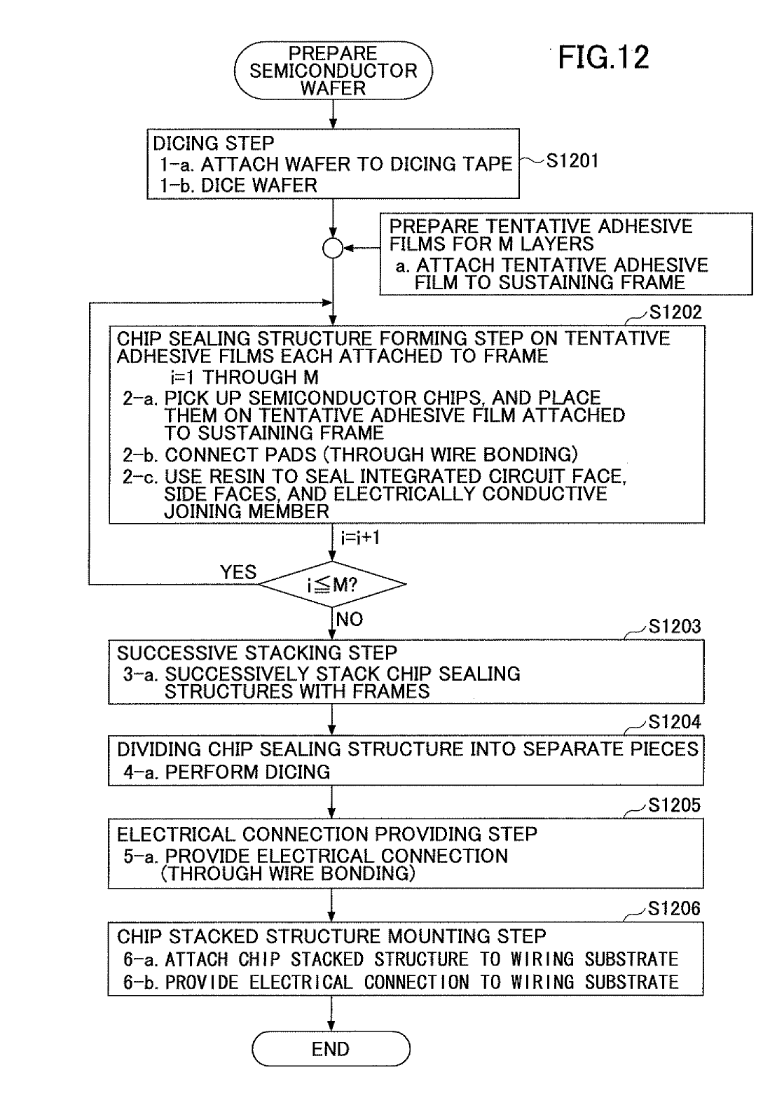

FIG. 12 is a flowchart illustrating a method of manufacturing semiconductor chip stacked structures in which semiconductor chips arranged in a matrix form are stacked one over another according to the fifth embodiment. The manufacturing method includes a dicing step S1201, a tentative adhesive film preparing step, a chip sealing structure forming step S1202 on tentative adhesive films each attached to a frame, a successive stacking step S1203, a chip sealing structure dividing step S1204, an electrical connection providing step S1205, and a chip stacked structure mounting step S1206.

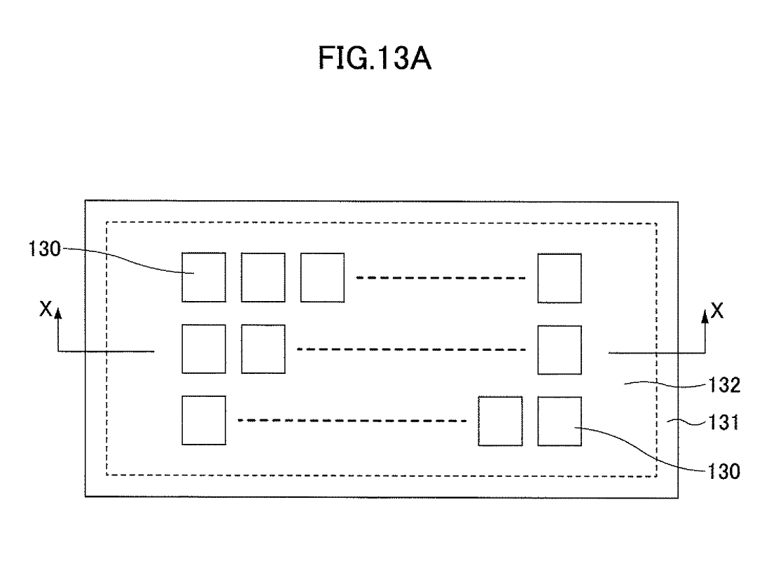

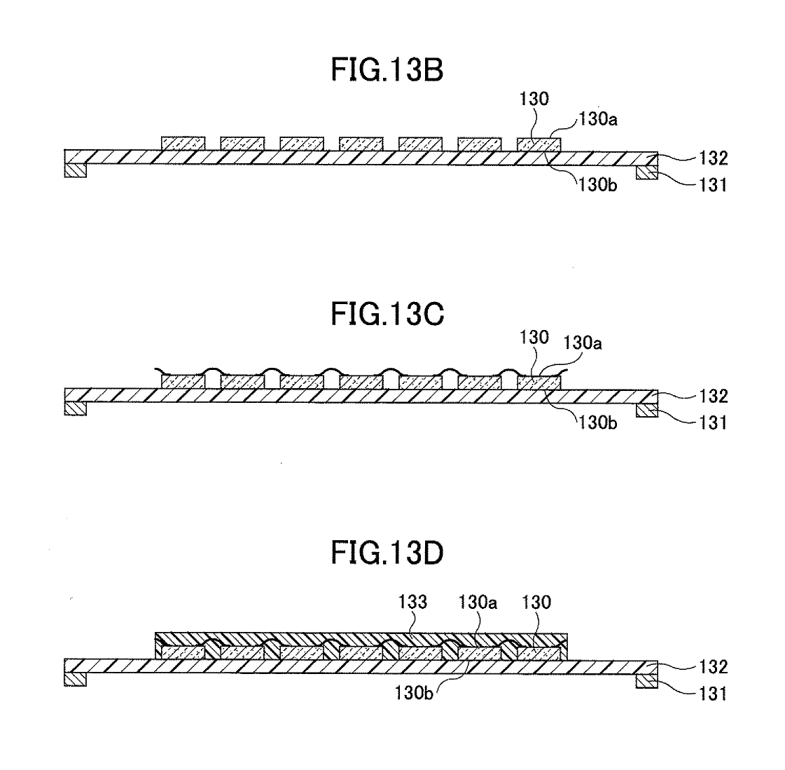

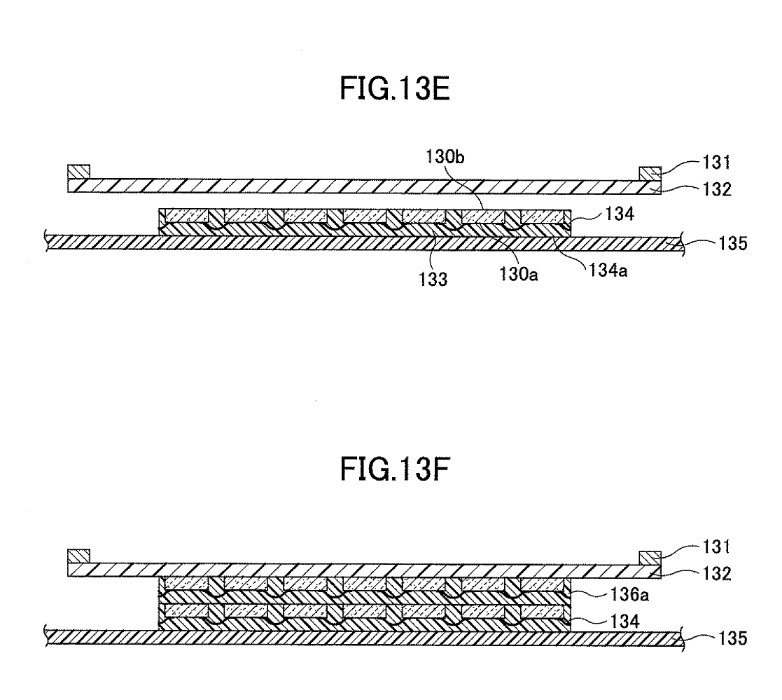

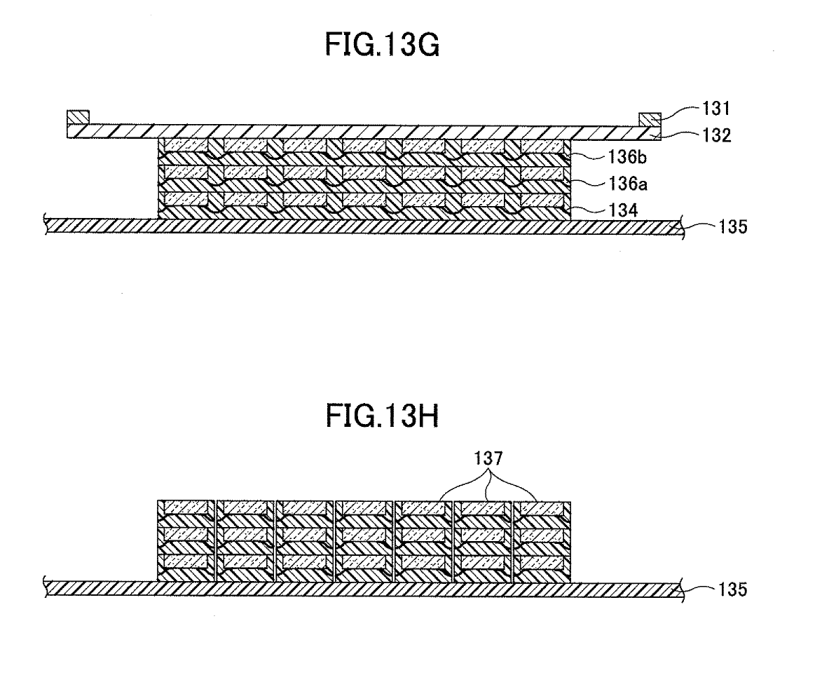

FIGS. 13A through 13H are drawings for illustrating some of the steps of the method of manufacturing semiconductor chip stacked structures in which semiconductor chips arranged in a matrix form are stacked one over another. In the following, a description will be given of the steps of the manufacturing method of FIG. 12 by referring to FIGS. 13A through 13H.

[Dicing Step S1201]

This dicing step is the same as the dicing step described in connection with the first and subsequent embodiments, and a description thereof will be omitted.

[Tentative Adhesive Film Preparing Step]

Tentative adhesive films, each attached to a sustaining frame, equal in number to the number of layers of stacked chip sealing structures are provided. The sustaining frame may be any support frame made of a material whose characteristics and shape do not change during the manufacturing steps. Each sustaining frame or tentative adhesive film has an alignment mark used at the time of making stacks.

[Chip Sealing Structure Forming Step S102 on Tentative Adhesive Films Each Attached to Frame]

Semiconductor chips are placed on tentative adhesive films, and are sealed with resin, thereby forming M sets of chip sealing structures for M layers.

[Sub-Step 2-a: Picking Up Semiconductor Chips, and Placing Chips on Frame-Attached Tentative Adhesive Films]

FIG. 13A illustrates diced semiconductor chips 130 picked up and arranged in a matrix form on a tentative adhesive film 132 attached to a sustaining frame 131. FIG. 13B illustrates a cross section taken along a line X-X in FIG. 13B. A back surface 130b opposite an integrated circuit surface 130a of each semiconductor chip 130 is adhered to the tentative adhesive film 132. During the process of applying resin for sealing, thus, no resin will be attached to the back surface. The array of semiconductor chips may have 3 rows and 7 columns, 3 rows and 10 columns, or the like, which are determined based on the size of semiconductor chips, the size of chip sealing structures, the dicing condition for dicing chip sealing structures, and the like.

[Sub-Step 2-b: Connecting Pads (Wire Bonding)]

Electrically conductive joining members (i.e., bonding wires) for providing electrical connections for chip sealing structures are connected to the pads of the semiconductor chips. The method and manner of connections are the same as or similar to those of the first embodiment.

FIG. 13C illustrates the semiconductor chips whose pads are connected.

[Sub-Step 2-c: Sealing Integrated Circuit Face, Side Faces, and Electrically Conductive Joining Members]

FIG. 13D illustrates resin 133 that seals integrated circuit faces, side faces, and electrically conductive joining members. The pad connections and sealing of integrated circuit faces with resin are the same as or similar to that of the step S102 of the first embodiment, and a description thereof will be omitted. When M layers of chip sealing structures are to be included in the stacks, M tentative adhesive films each attached to a frame are prepared, and are subjected to resin sealing.

A chip sealing structure 134 that is to be situated at the bottom layer of a chip stacked structure has, opposite the integrated circuit face 130a, the back face 130b that is to be sealed by the resin of another chip sealing structure.

As illustrated in FIG. 13E, a surface 134a of the sealing resin is brought in contact with a new tentative placement sheet 135, and the tentative adhesive film 132 is peeled off from the back surface 130b. This serves as a step of making it possible to further stack another layer on the back surface 130b. A material that has a surface easily removable from the resin 133 may be used for the tentative placement sheet 135. As will be described in step S1204, the material may have the function to serve as a dicing tape.

[Successive Stacking Step S1203]

Chip sealing structures to form respective layers are placed one after another, thereby achieving successive stacking. During this successive stacking, the tentative adhesive film 132 is removed from each chip sealing structure. Upon removal, the chip back face which is opposite the integrated circuit face is exposed at the surface of the sealing structure.

FIGS. 13F and 13G illustrate stacked chip sealing structures with a second layer 136a and a third layer 136b, respectively, at the top. In FIG. 13G, the resin is still in the semi-cured state (i.e., B stage) while the structures are stacked one over another. The positional alignment of layers upon stacking is performed by use of an optical mechanism and a positional control system, thereby securing positional precision.

[Dividing Chip Sealing Structure into Separate Pieces S1204]

This step uses a dicer apparatus to divide the stacked chip sealing structures in which the semiconductor chips are arranged in a matrix form. An optical mechanism and a positional control system are used to secure positional precision at the time of dicing the chip sealing structures into separate pieces. In so doing, the tentative placement sheet 135 serves also as a dicing tape.

FIG. 13H illustrates separate pieces into which the chip sealing structures are divided. Chip sealing structures 137 that are separate pieces are tentatively fixed on the tentative placement sheet 135 at predetermined intervals.

[Electrical Connection Providing Step S1205]

The separate chip stacked structures 137 are picked up, and are rotated by 90 degrees to align their stacking direction to a horizontal direction. Electrical connections are then provided by use of a wire bonder or the like. This provision of electrical connections is the same as or similar to sub-step 4-b in step S104 described in the first embodiment, and a description thereof will be omitted.

The next step S1206 of mounting a chip stacked structure is the same as or similar to the corresponding step of the first and subsequent embodiments in which mounting is performed while the sealing resin is kept in the semi-cured state (i.e., B-stage).

### Advantage of Fifth Embodiment

In the fifth embodiment, the dicing step is performed with respect to stacked chip sealing structures to make them into separate pieces at once. With this arrangement, not only the thickness of the semiconductor packages is reduced, but also the number of dicing operations for dividing the chip sealing structures is significantly reduced in comparison with the first embodiment. This simplifies the manufacturing steps, and also improves product quality.

Further, the present invention is not limited to these embodiments, but various variations and modifications with respect to the above-noted embodiments may be made without departing from the scope of the present invention.

The present application is based on Japanese priority application No. 2009-211367 filed on Sep. 14, 2009, with the Japanese Patent Office, the entire contents of which are hereby incorporated by reference.

What is claimed is:

1. A method of making a semiconductor chip stacked structure, comprising:
a dicing step of dicing a semiconductor wafer into semiconductor chips, the semiconductor chips respectively having a first surface and a second surface opposite thereto, the semiconductor chips having integrated circuits and pads on the first surfaces;
a first step of arranging the semiconductor chips at intervals on a film having an adhesive property with the second surfaces facing downward, connecting the pads through joining members, sealing with resin the joining members and surfaces of the semiconductor chips excluding the second surfaces to produce a chip sealing structure, and dividing the chip sealing structure to produce separate chip sealing structures having ends of the joining members exposed at surfaces thereof;
a second step of removing the film to expose the second surfaces of the semiconductor chips;
a third step of stacking the chip sealing structures one over another and connecting the exposed ends of the joining members through a bonding wire to produce a chip stacked structure; and
a fourth step of mounting the chip stacked structure on a wiring substrate to produce a semiconductor chip stacked structure.

2. The method as claimed in claim 1, wherein the film is a tentative adhesive film, and the arranging the semiconductor chips at intervals includes placing the semiconductor chips produced by the dicing step on the tentative adhesive film.

3. The method as claimed in claim 1, wherein the film is a dicing tape, and the arranging the semiconductor chips at intervals includes stretching and expanding the dicing tape used in the dicing step while the semiconductor chips produced by the dicing step are disposed on the dicing tape.

4. The method as claimed in claim 1, wherein the connecting the pads is performed by use of wire bonding.

5. The method as claimed in claim 4, wherein the wire bonding used for connecting the pads produces a bonding wire such that a shape of the bonding wire connecting between connection points as defined in a plane containing the bonding wire is a curve that has at least one dent.

6. The method as claimed in claim 1, wherein the first step, the third step, and the fourth step are performed while the resin used for sealing is in a semi-cured state.

7. The method as claimed in claim 1, further comprising a flip-chip connecting step of connecting a semiconductor chip to the wiring substrate in a flip-chip manner, the semiconductor chip belonging to one of the chip sealing structures that faces the wiring substrate.

8. A semiconductor chip stacked structure, comprising:
a plurality of chip sealing structures, each of which includes a semiconductor chip, a joining member, and resin sealing the semiconductor chip and the joining member, the semiconductor chip having a first surface and a second surface opposite thereto and having an integrated circuit and a pad on the first surface, the joining member having a first end thereof connected to the pad and a second end thereof exposed from the resin, and the second surface of the semiconductor chip being exposed from the resin;
a wiring substrate having a connection terminal; and
a bonding wire,
wherein the plurality of chip sealing structures are stacked on the wiring substrate, and the bonding wire connects the connection terminal of the wiring substrate and the second ends of the joining members of each chip sealing structure.

9. The semiconductor chip stacked structure as claimed in claim 8, wherein the semiconductor chip of a bottom one of the chip sealing structures stacked on the wiring substrate is flip-chip mounted on the wiring substrate.

10. The semiconductor chip stacked structure as claimed in claim 8, wherein the bonding wire is shaped into a curved arch or a letter-M shape.

11. The semiconductor chip stacked structure as claimed in claim 8, wherein at least one corner of the chip sealing structures is beveled to have a flat surface.

12. The semiconductor chip stacked structure as claimed in claim 8, wherein at least one corner of the chip sealing structures is beveled to have a curved surface.
